(19) United States
(12) Patent Application Publication
(10) Pub. No.: US 2023/0253516 A1
(43) Pub. Date: Aug. 10, 2023

(54) PHOTODETECTOR

(71) Applicant: Nippon Telegraph and Telephone Corporation, Tokyo (JP)

(72) Inventors: Tatsuro Hiraki, Tokyo (JP); Shinji Matsuo, Tokyo (JP)

(21) Appl. No.: 18/002,809

(22) PCT Filed: Jul. 22, 2020
(86) PCT No.: PCT/JP2020/028458

§ 371 Date: Dec. 21, 2022

(51) Int. Cl. H01L 31/0232; H01L 31/0304; H01L 31/113; H01L 31/18; G02B 6/13

(52) U.S. Cl. CPC H01L 31/02327; G02B 6/13; H01L 31/0304; H01L 31/1136; H01L 31/1844

(57) ABSTRACT

An embodiment photodetector includes a clad layer formed on a substrate, a first semiconductor layer formed on the clad layer, and a second semiconductor layer and a third semiconductor layer with the first semiconductor layer interposed therebetween formed on the clad layer. The photodetector includes a light absorbing layer made of an n-type III-V compound semiconductor formed on the first semiconductor layer through an insulating layer.

This patent application is a national phase filing under section 371 of PCT application no. PCT/JP2020/028458, filed on Jul. 22, 2020, which application is incorporated herein by reference in its entirety.

### TECHNICAL FIELD

The present invention relates to a waveguide type photodetector.

### BACKGROUND

The Si-based optical integrated circuit (Si optical integrated circuit) is a technique for realizing an optical signal processing circuit using near-infrared light on an inexpensive Si substrate, and is a key technique in the field of optical communication and optical computing. One of the component parts of the Si optical integrated circuit is a photodetector, and a p-i-n photodiode is widely used. Since the Si layer in which the optical waveguide is formed has a physical property transmitting near-infrared, Ge has been widely used for the absorption layer of the photodiode.

In the photodiode, the sensitivity (A/W) defined by a ratio of the input light intensity and light current, is one of the performance indexes, and the sensitivity is required to be high. However, the conventional p-i-n photodiode has a quantum efficiency limit (about 1.2 A/W for wavelength 1.55 µm), so that high sensitivity is difficult. Although it is also possible to increase the sensitivity by avalanche amplification, it is difficult to reduce the power consumption because the operating voltage is high.

On the other hand, a technique for realizing a photodetector having a high gain by using a gate of a MOSFET by a Si channel as a light absorbing layer has been reported (see NPL 1). In the photodetector, when light guided in an optical waveguide formed on the lower side of the gate is absorbed by the gate, a gate voltage changes according to the intensity of the light, and a current flowing between a source and a drain also changes. Since the high gain of the MOSFET causes a large change in drain current with respect to a slight change in incident light intensity, a high sensitivity operation is enabled. The Si channel MOSFET can achieve both high sensitivity and low voltage by a mature microfabrication technique. The band of the photodetector is smaller than the p-i-n photodiode, but the operation of the gigahertz class and the high sensitivity exceeding 100 A/W are realized.

### CITATION LIST

### Non Patent Literature

[NPL 1] R.W.Going et al., “Germanium Gate PhotoMOSFET Integrated to Silicon Photonics”, IEEE Journal of Selected Topics in Quantum Electronics, vol. 20, No. 4,8201607, 2014.

### SUMMARY

### Technical Problem

In the conventional technique, Ge is used for an absorbing layer (a gate material) of near-infrared light which is a communication wavelength band. However, an absorbing coefficient of Ge in a long wavelength region of 1.5 µm band or more is small. Therefore, the absorbing length is increased to obtain sufficient light absorption, and the size of the MOSFET is increased. In addition, when electrons having high mobility are used as a channel, although the GE gate must be an n-type semiconductor, it is generally difficult to reduce the contact resistance of the contact between the n-type Ge and the metal due to Fermi level pinning. These are factors that prevent the miniaturization and the reduction in resistance of the element.

Embodiments of the present invention have been made to solve the above-mentioned problems, and it is intended to reduce the size and resistance of a photodetector having the gate of the MOSFET as a light absorbing layer.

### Solution to Problem

A photodetector according to embodiments of the present invention includes a first semiconductor layer made of p-type silicon formed on a clad layer and having an optical waveguide optically connected to one end side in a waveguide direction, a second semiconductor layer and a third semiconductor layer made of n-type silicon formed on the clad layer with the first semiconductor layer interposed therebetween, a light absorbing layer made of an n-type III-V group compound semiconductor formed on the first semiconductor layer through an insulating layer, a first electrode electrically connected to the light absorbing layer in a region other than a region on the first semiconductor layer, a second electrode electrically connected to the second semiconductor layer, and a third electrode electrically connected to the third semiconductor layer.

### Advantageous Effects of Embodiments of the Invention

As described above, according to embodiments of the present invention, since the light absorbing layer is formed of the n-type III-V group compound semiconductor, the photodetector having the gate of the MOSFET as the light absorbing layer can be miniaturized and reduced in resistance.

### BRIEF DESCRIPTION OF THE DRAWINGS

FIG. 1A is a cross sectional view of a photodetector according to an embodiment of the present invention.

FIG. 1B is a plan view of a photodetector according to an embodiment of the present invention.

FIG. 2 is a cross sectional view showing another photodetector according to an embodiment of the present invention.

FIG. 3 is a characteristic diagram showing a calculation result of sensitivity of a photodetector.

FIG. 4 is a plan view showing a configuration of another photodetector according to an embodiment of the present invention.

FIG. 5 is a cross sectional view showing a configuration of another photodetector according to an embodiment of the present invention.

### DETAILED DESCRIPTION OF ILLUSTRATIVE EMBODIMENTS

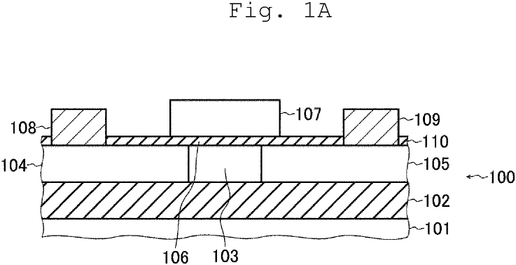

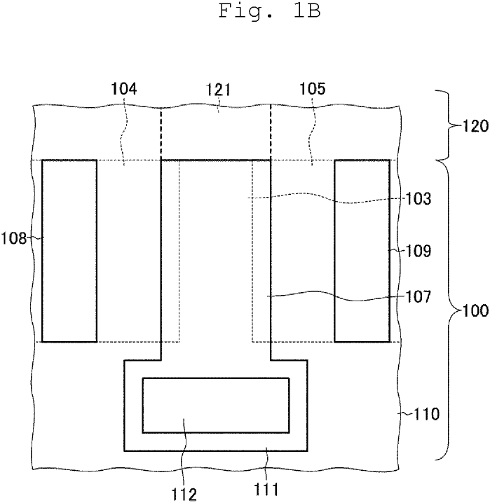

Hereinafter, a photodetector 100 according to an embodiment of the present invention will be described with reference to FIG. 1A and FIG. 1B. The photodetector 100 includes a clad layer 102 formed on a substrate 101, a first semiconductor layer 103 formed on the clad layer 102, and a second semiconductor layer 104 and a third semiconductor layer 105 formed on the clad layer 102 with the first semiconductor layer 103 interposed therebetween.

The first semiconductor layer 103 is made of a p-type silicon. The first semiconductor layer 103 has, for example, a thickness of 220 nm. An optical waveguide 120 is optically connected to one end side in the waveguide direction of the first semiconductor layer 103. The second semiconductor layer 104 and the third semiconductor layer 105 are made of an n-type silicon. The second semiconductor layer 104 and the third semiconductor layer 105 are formed continuously to the first semiconductor layer 103, and have a thickness of, for example, 220 nm.

The photodetector 100 also includes a light absorbing layer 107 formed on the first semiconductor layer 103 through an insulating layer 106 and made of an n-type III-V group compound semiconductor. The light absorbing layer 107 can be made of the III-V group compound semiconductor having a band gap energy absorbing near-infrared light, such as InGaAs. Note that, it is desirable that the light absorbing layer 107 includes the III-V group compound semiconductor capable of absorbing near-infrared light in a communication wavelength band of 1.3 µm band or more, and it may be made of InAs, for example. InAs has an absorbing coefficient higher than that of InGaAs. The light absorbing layer 107 has a thickness of 200 nm.

In the light absorbing layer 107, a width in a direction parallel to the plane of the clad layer 102 is set to be a dimension (for example, 400 nm) almost matched with the single mode condition of the optical waveguide 120 in a cross section perpendicular to the waveguide direction. This width corresponds to the gate length of the MOSFET structure described later. The insulating layer 106, for example, can include SiO2. The thickness of the insulating layer 106 can be about 10 nm. The insulating layer 106 as the gate insulating layer is made thinner than 10 nm or made of a material having a higher dielectric constant as described later, so that a higher gate electric field can be obtained at a lower gate voltage, and a higher sensitivity of the photodetector 100 can be obtained at low voltage, as will be described later.

The photodetector 100 is an n-channel type MOSFET structure in which the first semiconductor layer 103 is a channel layer, the second semiconductor layer 104 is a source, the third semiconductor layer 105 is a drain, and the light absorbing layer 107 is a gate. The insulating layer 106 serves as a gate insulating layer. The first semiconductor layer 103 on which the light absorbing layer 107 is disposed, the second semiconductor layer 104, and the third semiconductor layer 105 constitute a so-called rib-type optical waveguide. It is important that the distance between the first semiconductor layer 103 and the light absorbing layer 107 in the thickness direction viewed from the clad layer 102 can be optically coupled to each other, and the electric field from the light absorbing layer 107 can be applied to the first semiconductor layer 103.

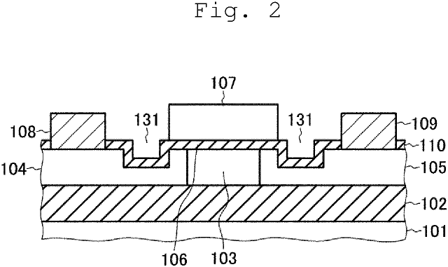

In the optical waveguide having the above-described structure, for example, as shown in FIG. 2, by forming a groove 131 on both sides of the waveguide direction of the light absorbing layer 107 and thinning the second semiconductor layer 104 and the third semiconductor layer 105 in this part, high light confinement to the first semiconductor layer 103 is enabled. In addition, such a structure can reduce variation in characteristics due to positional deviation between the grooves 131 on both sides of the first semiconductor layer 103 and the light absorbing layer 107 in a cross section perpendicular to the waveguide direction.

The photodetector 100 includes a first electrode 112 electrically connected to the light absorbing layer 107 in a contact region 111 other than a region on the first semiconductor layer 103, a second electrode 108 electrically connected to the second semiconductor layer 104, and a third electrode 109 electrically connected to the third semiconductor layer 105. The first electrode 112, the second electrode 108, and the third electrode 109 are made of metal. The first semiconductor layer 103 can be in a state (a floating state) in which the potential is not fixed. For this reason, the electrode electrically connected in a region not shown can be provided in the first semiconductor layer 103 to fix the potential of the first semiconductor layer 103.

In the embodiment, the optical waveguide 120 formed by a core 121 made of silicon (Si) is optically connected to one end side of the first semiconductor layer 103 in the waveguide direction. The core 121 is formed continuously to the first semiconductor layer 103, for example, and has a thickness of 220 nm and a core width of 400 nm. The optical waveguide 120 formed by the core 121 of this size can be a single mode. The optical waveguide formed by the first semiconductor layer 103 in the photodetector 100 can be optically coupled to the optical waveguide 120 in a single mode.

The first semiconductor layer 103, the second semiconductor layer 104, the third semiconductor layer 105, and a region other than the second electrode 108 and the third electrode 109 on the core 121 are covered with the insulating layer 110. The insulating layer 110 is formed continuously with the insulating layer 106. In the optical waveguide 120, the clad layer (not shown) above the core 121 may be provided through the insulating layer 110. In the region of the optical waveguide 120, the insulating layer 110 may be made thick to form an upper clad layer. Note that the thickness of the core 121 is not limited to 220 nm, and can be set within a film thickness range of 100 to 300 nm which the optical waveguide 120 operates in a single mode. The width and thickness of the light absorbing layer 107 which enables low-loss coupling with the optical waveguide 120 are determined according to the dimension (the thickness) of the core 121.

The fabrication of the photodetector 100 is briefly described. First, a well-known SOI (Silicon on Insulator) substrate is prepared. The base portion of the SOI substrate serves as a substrate 101, and the buried insulating layer serves as the clad layer 102. The surface silicon layer of the SOI substrate is patterned by known lithography and etching techniques to form the first semiconductor layer 103, the second semiconductor layer 104, the third semiconductor layer 105, and a part of the core 121.

Next, impurities such as phosphorus and arsenic are introduced into the second semiconductor layer 104 and the third semiconductor layer 105 by a well-known ion implantation method or the like to make the second semiconductor layer 104 and the third semiconductor layer 105 n-type. Next, on the first semiconductor layer 103, the second semiconductor layer 104, the third semiconductor layer 105, and the core 121, for example, the insulating layers 106 and 110 are formed by depositing an insulating material such as silicon oxide by a well-known CVD method or the like.

On the other hand, another substrate made of InP or the like is prepared, and a compound semiconductor layer made of n-type InGaAs is formed on the substrate. These formations can be carried out by epitaxial growth by a known organometallic vapor phase growth method or molecular beam epitaxial growth method.

Next, the surface of the compound semiconductor layer and the surface of the insulating layer 110 (the insulating layer 106) are bonded by a surface activated bonding method, for example, to bond another substrate to the substrate 101. Next, the other substrate is thinned from the rear surface side by, for example, a well-known polishing method or the like, the other substrate is removed, and the compound semiconductor layer is formed on the insulating layer 110 (the insulating layer 106).

Next, by patterning the above mentioned compound semiconductor layer using a known lithography technique and a known etching technique, the light absorbing layer 107 and the contact region 111 are formed. Next, a contact hole is formed in the insulating layer 110 where the second electrode 108 and the third electrode 109 are formed. Thereafter, the first electrode 112, the second electrode 108, and the third electrode 109 are formed by deposition of a predetermined electrode material by a sputtering method, a vapor deposition method, or the like, and a lift-off method.

Next, an operation of the photodetector 100 will be described. For example, the light guided through the optical waveguide 120 and incident on the photodetector 100 is absorbed by the light absorbing layer 107 in a process of guiding the light with the first semiconductor layer 103 as the center of the mode in a cross-sectional view. When a positive voltage is applied between the light absorbing layer 107 and the third semiconductor layer 105, an inversion layer is formed at the interface between the first semiconductor layer 103 and the insulating layer 106 where the channel of the MOSFET structure described above is formed. When a gate electric field is applied by the light absorbing layer 107 to which a gate voltage is applied, a channel resistance between the second semiconductor layer 104 serving as a source and the third semiconductor layer 105 serving as a drain changes.

In a state where a constant gate voltage is applied to the light absorbing layer 107 and light is absorbed in the light absorbing layer 107, as described above, the gate voltage changes according to the intensity of the absorbed light. As a result, the channel resistance between the second semiconductor layer 104 and the third semiconductor layer 105 serving as the drain changes, and the drain current also changes. Since a large change in drain current is generated with respect to a change in light intensity absorbed by the light absorbing layer 107 due to a high gain of the MOSFET, a highly sensitive operation is enabled in the photodetector 100.

In the photodetector 100, since the light absorbing layer 107 is formed of the III-V group compound semiconductor having the absorbing coefficient higher than that of Ge, the light with a short absorbing length (a gate width) can be absorbed. Further, since the light absorbing layer 107 is formed of a III-V group compound semiconductor, it is easy to form a contact having a lower resistance than that of Ge. Such a technique for forming the contact between an electrode and a semiconductor layer is generally used in a semiconductor laser. Due to these features, the photodetector 100 has a structure that can be easily miniaturized and reduced in resistance as compared with a conventional technique using the MOSFET with n-Ge as a photodetector.

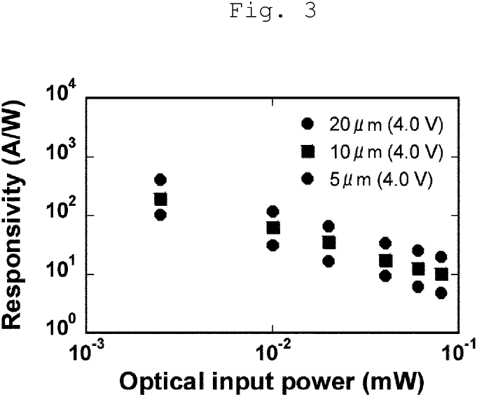

FIG. 3 shows the results of the calculation of the sensitivity of the photodetector 100. The thickness of the insulating layer 106 is 10 nm, and the wavelength of incident light is 1.55 µm. The photocurrent is a current value obtained by removing a drain current in a dark state from a drain current at the time of incidence of light. The incident light intensity is the light intensity incident on the optical waveguide 120, and is an estimate of sensitivity including coupling loss between the optical waveguide 120 and the optical waveguide in the MOSFET structure (the photodetector 100). In this calculation, the gate leakage current due to the tunnel effect is not considered.

A voltage (a gate voltage) applied to the light absorbing layer 107 and a voltage (a drain voltage) applied between the second semiconductor layer 104 and the third semiconductor layer 105 are both 4 V. The absorbing length (the gate width) which is the length of the light absorbing layer 107 in the waveguide direction is set to a three kind of 5 µm, 10 µm, and 20 µm. The results of the calculation show that the sensitivity decreases as the optical input increases, but this results from the nonlinearity of the photovoltaic power. It can be seen that sensitivity close to 100 A/W is achieved even in an absorbing length of about 5 µm in a region where the optical power is low.

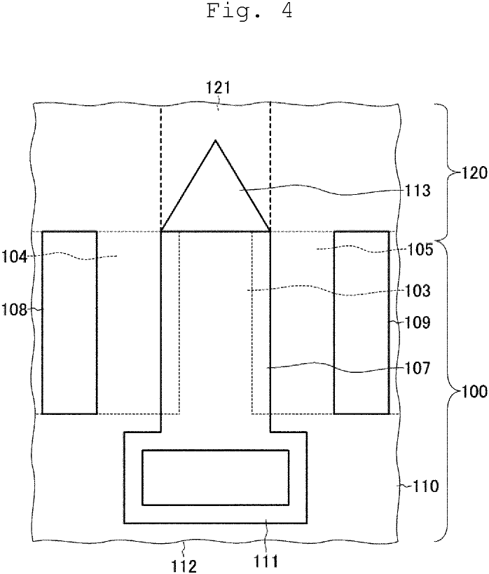

As shown in FIG. 4, a tapered part 113 formed continuously with the light absorbing layer 107 can be provided on the region of the optical waveguide 120 (upper part of the core 121). The tapered part 113 has the same thickness as the light absorbing layer 107. The tapered part 113 has a shape that the width in a plan view becomes narrower as it is separated from the light absorbing layer 107. The tapered part 113 can achieve lower loss optical coupling between the optical waveguide 120 and the photodetector 100. The tapered part 113 can be constituted of the III-V group compound semiconductor. The tapered part 113 is not required to be the same group III-V compound semiconductor as the light absorbing layer 107, and can be constituted of different III-V group compound semiconductors lattice-matched with the light absorbing layer 107. The tapered part 113 is preferably composed of the III-V group compound semiconductor having a band gap energy which does not absorb the incident light as an object.

Further, the light absorbing layer 107 can be set in a state in which the density (the concentration) of the impurity (the donor) is higher as the light absorbing layer 107 is separated farther from the clad layer 102 side in the thickness direction. For example, the donor density should be higher in order to reduce the contact resistance with the first electrode 112 and the gate resistance in the light absorbing layer 107. On the other hand, in the III-V compound semiconductor group having a small effective mass, when the donor density becomes high, remarkable band filling occurs, and the band gap is effectively widened, and the light absorbing coefficient becomes small. Therefore, in order to maintain a high light absorbing coefficient, the density and concentration of the donor can be small except for the uppermost layer forming the contact with the first electrode 112. In this structure, it is possible that the density of the impurity in the light absorbing layer 107 is higher, as the light absorbing layer 107 is separated farther from the clad layer 102 side in the thickness direction.

Although the thickness of the depletion layer and the threshold value of the MOSFET when the gate voltage is applied vary depending on the donor density of the insulating layer 106 and the vicinity of the light absorbing layer 107, they affect the sensitivity of the photodetector 100. The density of the light absorbing layer 107 near the film of the insulating layer 106 is determined in consideration of the density of donor and acceptor and operating voltage on the side of the clad layer 102.

Further, the light absorbing layer 107 can have a state in which the band gap energy is larger as it is separated farther from the side of the clad layer 102. This can be realized by forming the light absorbing layer 107 from the ternary III-V group compound semiconductor such as InGaAs. By changing the composition of the compound semiconductor constituting the light absorbing layer 107 within a range for lattice matching with the InP-based material, for example, the above-mentioned distribution of the band gap energy can be formed. The absorbing coefficient can be controlled by controlling the distribution of the band gap energy.

For example, a laminated structure can be formed in which a composition of a band gap energy having the high absorbing coefficient is formed near the insulating layer 106 and a band gap energy having the low absorbing coefficient is formed on the upper layer. Since the light absorbing coefficient is higher when the band gap energy is smaller, the light absorbing layer 107 near the insulating layer 106 has a lower band gap energy with the above mentioned structure, and the region above the light absorbing layer 107 has a higher band gap energy. With this structure, carriers can be generated only in the vicinity of the insulating layer 106 to be depleted. In this way, the photo-carrier distribution can be controlled by the laminated structure of the III-V group compound semiconductor having a plurality of band gaps. Further, a multi-quantum well can be provided in a part of the light absorbing layer 107. The light absorbing coefficient of the light absorbing layer 107 can be controlled by introducing a quantum confinement effect and distortion. Of course, the light absorbing coefficient can be controlled by changing both the donor density and the band gap in the thickness direction.

In the photodetector 100, since the photo-carriers generated in the light absorbing layer 107 cannot be extracted, the recombination of the photo-carriers needs to be delayed. This limits the response speed. As the recombination rate of the photo-carriers in the light absorbing layer 107 increases, the response speed increases. The recombination rate can be controlled by the carrier concentration distribution in the light absorbing layer 107. For example, when the light absorbing layer 107 is made of an InP-based material, the higher the carrier concentration, the more the Auger recombination becomes remarkable, and the recombination rate increases.

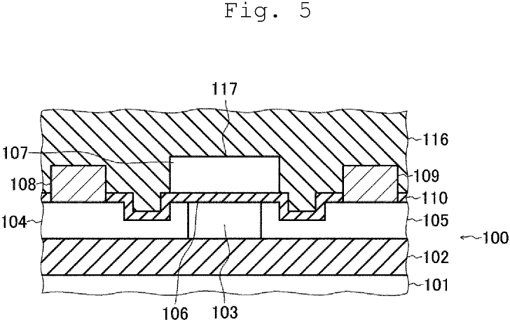

As shown in FIG. 5, the insulating layer 116 covering the light absorbing layer 107 may be provided, and a high defect density layer 117 formed at the interface between the light absorbing layer 107 and the insulating layer 116 may be introduced. The high defect density layer 117 is a region having a defect density larger than that of the inside of the light absorbing layer 107. By using the high defect density layer 117, the recombination rate on the surface of the light absorbing layer 107 can be increased.

For example, the InP-based semiconductor material can have the high defect density area with SiO2, and by coating the light absorbing layer 107 with an insulating layer 116 including SiO2 or the like, the high defect density layer 117 can be introduced and is effective for increasing the recombination rate. Thus, the operation speed can be improved. Since the increase of the recombination rate is a factor of deteriorating the sensitivity, it is designed in consideration of the trade-off between the sensitivity and the speed. When the recombination rate is desired to be reduced in order to improve the sensitivity, it is necessary to design the material and the method of forming the insulating layer 116 provided in contact with the light absorbing layer 107. For example, it is known that an interface between an Al2O3 layer formed by an atomic layer deposition method and an InP-based semiconductor layer has a small defect density, and the surface recombination rate of the light absorbing layer 107 can be reduced.

As described above, according to embodiments of the present invention, since the light absorbing layer is formed of the n-type III-V group compound semiconductor, the photodetector having the gate of the MOSFET as the light absorbing layer can be miniaturized and reduced in resistance.

Note that the embodiments of the present invention are not limited to the embodiments described above, and it is clear that many modifications and combinations can be carried out by those having ordinary knowledge in the art within the technical ideas of the present invention.

| | Reference Signs List |
|---|---|
| 100 | Photodetector |
| 101 | Substrate |
| 102 | Clad layer |
| 103 | First semiconductor layer |
| 104 | Second semiconductor layer |
| 105 | Third semiconductor layer |
| 106 | Insulating layer |
| 107 | Light absorbing layer |
| 108 | Second electrode |
| 109 | Third electrode |
| 110 | Insulating layer |
| 111 | Contact region |
| 112 | First electrode |
| 120 | Optical waveguide |
| 121 | Core |

1-5. (canceled)

6. A photodetector comprising:
a first semiconductor layer comprising p-type silicon on a clad layer;
a second semiconductor layer and a third semiconductor layer on the clad layer with the first semiconductor layer interposed therebetween, the second semiconductor layer and the third semiconductor layer comprising n-type silicon;
a light absorbing layer on the first semiconductor layer, the light absorbing layer comprising an n-type III-V group compound semiconductor;
a first electrode electrically connected to the light absorbing layer in a region other than a region above the first semiconductor layer;
a second electrode electrically connected to the second semiconductor layer; and
a third electrode electrically connected to the third semiconductor layer.

7. The photodetector according to claim 6, further comprising an optical waveguide optically connected to a first end side of the first semiconductor layer.

8. The photodetector according to claim 6, wherein the density of impurities in the light absorbing layer is higher as a distance between the light absorbing layer and the clad layer is increased.

9. The photodetector according to claim 6, wherein the light absorbing layer comprises a ternary III-V group compound semiconductor, and wherein a band gap energy increases as a distance between the light absorbing layer and the clad layer increases.

10. The photodetector according to claim 6, further comprising:
an insulating layer on the light absorbing layer; and
a high defect density layer on an interface between the light absorbing layer and the insulating layer, the high defect density layer having a defect density larger than that of an inside region of the light absorbing layer.

11. The photodetector according to claim 6, further comprising:
a first insulating layer on the first semiconductor layer, wherein the light absorbing layer is on the first insulating layer; and
a second insulating layer on the light absorbing layer.

12. The photodetector according to claim 11, further comprising a high defect density layer on an interface between the light absorbing layer and the second insulating layer, the high defect density layer having a defect density larger than that of an inside region of the light absorbing layer.

13. A method of forming a photodetector, the method comprising:
forming a first semiconductor layer comprising p-type silicon on a clad layer;
forming a second semiconductor layer and a third semiconductor layer on the clad layer with the first semiconductor layer interposed therebetween, the second semiconductor layer and the third semiconductor layer comprising n-type silicon;
forming an insulating layer on the first semiconductor layer, the second semiconductor layer, and the third semiconductor layer;
forming a light absorbing layer on the first semiconductor layer, the light absorbing layer comprising an n-type III-V group compound semiconductor;
forming a first electrode electrically connected to the light absorbing layer in a region other than a region above the first semiconductor layer;
forming a second electrode electrically connected to the second semiconductor layer; and
forming a third electrode electrically connected to the third semiconductor layer.

14. The method according to claim 13, further comprising forming an optical waveguide optically connected to a first end side of the first semiconductor layer.

15. The method according to claim 13, wherein the density of impurities in the light absorbing layer increases as a distance between the light absorbing layer and the clad layer is increased.

16. The method according to claim 13, wherein the light absorbing layer comprises a ternary III-V group compound semiconductor, and wherein a band gap energy increases as a distance between the light absorbing layer and the clad layer increases.

17. The method according to claim 13, further comprising:
forming a second insulating layer on the light absorbing layer; and
forming a high defect density layer on an interface between the light absorbing layer and the insulating layer, the high defect density layer having a defect density larger than that of an inside region of the light absorbing layer.
